(19) United States
(12) Patent Application Publication
(10) Pub. No.: US 2018/0006177 A1
(43) Pub. Date: Jan. 4, 2018

(54) FLEXIBLE CONDUCTING COVER GLASS REPLACEMENT FOR SATELLITE SOLAR PANELS

(71) Applicant: New Mexico Tech Research Foundation, Socorro, NM (US)

(72) Inventors: Phillip Clift, Buffalo, WY (US); Jordan Wladyka, Las Cruces, NM (US); Tyler Payton, Gallup, NM (US)

(21) Appl. No.: 15/639,802

(22) Filed: Jun. 30, 2017

Related U.S. Application Data
(60) Provisional application No. 62/357,197, filed on Jun. 30, 2016.

(51) Int. Cl. H01L 31/048; C08K 3/22; C08K 7/20; C03C 12/00; H01L 31/054; C08K 5/092; H01L 31/02; C01G 9/03

(52) U.S. Cl. CPC H01L 31/0481; H01L 31/02008; C08K 3/22; C01G 9/03; C03C 12/00; H01L 31/054; C08K 5/092; C08K 7/20; C01P 2002/60; C01P 2004/30; C01P 2004/50; C01P 2006/40; C08K 2003/2296; C08K 2201/001; C08K 2201/005

(57) ABSTRACT

A composition for covering satellite solar panels includes an encapsulating resin, a conductive nano-network, and fused silica/quartz beads. A coverglass for a satellite solar panel includes such a composition. A method for producing the composition includes the steps of mixing an encapsulating resin, a conductive nano-network, and fused silica/quartz beads at a specific ratio, so that the ratio maximizes the inherent properties; and tape casting the mixture to create the composition.

### CROSS REFERENCE TO RELATED APPLICATIONS

This application claims the benefit of U.S. Provisional Application No. 62/357,197, filed Jun. 30, 2016, which is incorporated herein by reference in its entirety.

### TECHNICAL FIELD

The subject matter disclosed herein is generally directed to solar cell semiconductor devices. Specifically, the present disclosure is related to a cover glass replacement for modern composites used on satellite solar panels to provide protection from radiation, oxygen bombardment, and debris.

### BACKGROUND

The present invention relates generally to solar cell semiconductor devices, and particularly to the composition and structure of cover glass replacements for satellite solar panels.

Standard space solar arrays generally consist of a plurality of solar cells that are adhered in some manner to substantially rigid patent substrates and then covered with glass microsheets. The combination of the substrates and in particular the glass microsheets provide protection from radiation, oxygen bombardment, and debris.

In satellite and other space-related applications, the size, mass, and cost of a satellite power system are dependent on the power and energy conversion efficiency of the solar cells used. In other words, the size of the payload and the availability of on-board services are proportional to the amount of power provided. Solar cells are often fabricated in vertical multi-functional structures, and disposed in horizontal arrays, with the individual solar cells connected together in a series. The shape and structure of an array, as well as the number of cells it contains, are determined in part by the desired output voltage and current.

After a solar cell is made, it typically is bonded with a cover glass material. The use of solar cells in space presents additional challenges for composition of the cover glass material that are unique to space applications and which are not addressed by the types of cover glass used in terrestrial applications.

Known also as interveted metamorphic multi junction OMNI) solar cells, these flexible solar cell arrays have demonstrated a significantly lower mass and substantially greater conversion efficiency. However, incorporation of this type of solar cell array into the standard rigid panel substrate and cover glass design essentially cancels out any advantages with regard to flexibility and mass associated with the IMM.

Cover glass materials that are commonly used on flexible solar arrays, for example, ITO and AZO are relatively transparent in terms of optical transmittance, but are associated inferior conductivity to prevent charge build-up from ambient radiation and thruster plumage. In order to fulfill basic design requirements, a replacement cover glass composite must be mechanically flexible, optically transparent, and conductive.

Cover glass materials are also associated with mobile phone applications. For example, attempts have been made to create a transparent mobile phone. However, the costs are high due to the complex circuitry and processing in order to make a conductive polymer.

A need therefore exists for a cover glass replacement material that is suitable for use with a low mass, flexible solar array that is environmentally stable, mechanically flexible, optically transparent, and conductive. Further, a need exists for a conductive, transparent polymer material that can be made cost-effectively and that can be utilized in applications requiring less expensive alternatives to known polymers, such as in cell phones and automotive technology.

### SUMMARY OF THE INVENTION

In one aspect, the invention provides a composition for covering satellite solar panels, comprising an encapsulating resin, a conductive nano-network, and glass beads. In one embodiment, the composition comprises a low outgassing polymer, or a silicon polymer, or both. In another embodiment, the composition further comprises glass beads for reduction of internal light scattering. In another embodiment, the glass beads comprise silica/quartz or an engineering ceramic. In further embodiments, the glass beads promote the transmission of light and block or absorbs cosmic and gamma radiation, or the glass beads comprise a size from about 5 microns to about 50 microns, or the glass beads are mixed at a weight ratio of 0.9:1 of beads to resin or a weight ratio of 2:1 of beads to resin. In another embodiment, the composition further comprises a shear thinning agent. In further embodiments, the conductive nano-network comprises two different nanocrystals, for example a range of 1-6 wt % of ZnO nanocrystals. In other embodiments, the two different nanocrystals comprise zinc oxide agglomerates and zinc oxide tetrapods. Further embodiments provide that the zinc oxide agglomerates comprise a mixture of one or more of zinc acetate dihydrate, zinc chloride, zinc monohydrate, and zinc nitrate hexahydrate. In another embodiment, the composition further comprises citric acid and deionized water, or the composition is prepared at molar ratio of 1:5 of the mixture to water. In another embodiment, the zinc oxide tetrapods are synthesized by the chemical vapor transport method or the vapor transport method. In another embodiment, the chemical vapor transport method comprises a 5:1 weight ratio of zinc carbonate powder to graphite powder, or the particle size range of graphite powder is about 20 micrometers. In another embodiment, the vapor transport method comprises pure zinc powder, or the particle size of the zinc powder is between about 5 to about 300 micrometers. In another embodiment, the encapsulating resin, the conductive nano-network, and the fused silica/quartz beads are mixed at specific ratios for maximizing the inherent properties and tape casted. In other embodiments, the composition is flexible and conductive, or the conductivity provides an advantage as a sensor to detect damage from space debris, such as meteorite penetration or ablation. In another embodiment, the composition can be utilized in terrestrial, extraterrestrial, and automotive applications, such as for a sensor or detector for replacement of touchscreen material for a display screen, or a damage detector for windshields.

In another aspect, the invention provides a coverglass for a satellite solar panel, comprising a composition as described herein. In one embodiment, the life span of the array is extended compared to a coverglass made from other materials, and wherein the volume required for compartmentalizing the solar array within the vehicle is reduced. In another embodiment, the coverglass is flexible and conductive.

In another aspect, the invention provides a method for producing a composition as described herein, comprising: mixing an encapsulating resin, a conductive nano-network, and fused silica/quartz beads at a specific ratio, wherein the ratio maximizes the inherent properties; and tape casting the mixture to create the composition. In one embodiment, the encapsulating resin optionally includes a low-out gassing polymer, or an encapsulating silicone polymer, or both. In another embodiment, the composition further comprises glass beads for reduction of internal light scattering. In another embodiment, the glass beads comprise silica/quartz or an engineering ceramic, or the glass beads promote the transmission of light and block or absorbs cosmic and gamma radiation, or the glass beads comprise a size from about 5 microns to about 50 microns, or the glass beads are mixed at a weight ratio of 0.9:1 of beads to resin or a weight ratio of 2:1 of beads to resin. In another embodiment, composition further comprises a shear thinning agent. In another embodiment, the conductive nano-network comprises two different nanocrystals, such as zinc oxide agglomerates and zinc oxide tetrapods. In another embodiment, the composition comprises a range of 1-6 wt % of ZnO nanocrystals. In another embodiment, the zinc oxide agglomerates comprise a mixture of one or more of zinc acetate dihydrate, zinc chloride, zinc monohydrate, and zinc nitrate hexahydrate. In another embodiment, the method further comprises citric acid and deionized water. In another embodiment, the composition is prepared at a molar ratio of 1:5 of the mixture to water. In another embodiment, the zinc oxide tetrapods are synthesized by the chemical vapor transport method or the vapor transport method. In another embodiment, the chemical vapor transport method comprises a 5:1 weight ratio of zinc carbonate powder to graphite powder, or the particle size range of graphite powder is about 20 micrometers. In another embodiment, the vapor transport method comprises pure zinc powder, or the particle size of the zinc powder is between about 5 to about 300 micrometers. In another embodiment, the encapsulating resin, the conductive nano-network, and the fused silica/quartz beads are mixed at specific ratios for maximizing the inherent properties and tape casted. In another embodiment, the composition is flexible and conductive, or the conductivity provides an advantage as a sensor to detect damage from space debris, such as penetration or ablation. In another embodiment, the composition can be utilized in terrestrial, extraterrestrial, and automotive applications, such as a sensor or detector for replacement of touchscreen material for a display screen, or a damage detector for windshields.

### BRIEF DESCRIPTION OF THE DRAWINGS

These and other features and advantages of the invention will be better and more fully appreciated by reference to the following detailed description when considered in conjunction with the accompanying drawings. In the drawings:

FIG. 1—Shows an overview of an apparatus for manufacture of a composition for replacement coverglass material for flexible solar arrays.

FIG. 2—Shows an enlarged cross-sectional view of a solar cell utilizing the composite according to the present invention. Left side shows SEM image of ZnO-T and right side shows SEM image of ZnO-A.

FIG. 3—Shows an image of ZnO tetrapods in a crucible boat.

FIG. 4—Shows am SEM image of tetrapods agglomerating onto glass microspheres.

FIG. 5—Shows the UV/VIS spectra of the ZnO-T and ZnO-A composites.

FIG. 6—Shows a conductance plot showing conductivity of composite materials with ZnO.

FIG. 7—Shows conductivity data for a composition of the present invention.

FIG. 8—Shows solar array damaged by a meteorite.

FIG. 9—Shows an SEM image of ZnO-T.

FIG. 10—Shows a general view of a tape cast and doctor blade set-up.

FIG. 11—Shows an image of a casted composite.

FIG. 12—Shows a side view of a final application of a coverglass in accordance with the invention to a solar array.

### DETAILED DESCRIPTION OF THE EXAMPLE EMBODIMENTS

Unless defined otherwise, technical and scientific terms used herein have the same meaning as commonly understood by one of ordinary skill in the art to which this disclosure pertains.

As used herein, the singular forms “a,” “an,” and “the” include both singular and plural referents unless the context clearly dictates otherwise.

The term “optional” or “optionally” means that the subsequently described event, circumstance or substituent may or may not occur, and that the description includes instances where the event or circumstance occurs and instances where it does not.

The recitation of numerical ranges by endpoints includes all numbers and fractions subsumed within the respective ranges, as well as the recited endpoints.

The terms “about” or “approximately” as used herein when referring to a measurable value such as a parameter, an amount, a temporal duration, and the like, are meant to encompass variations of and from the specified value, such as variations of +/−10% or less, +1-5% or less, +/−1% or less, and +/−0.1% or less of and from the specified value, insofar as such variations are appropriate to perform in the disclosed invention. It is to be understood that the value to which the modifier “about” or “approximately” refers is itself also specifically, and preferably, disclosed.

Reference throughout this specification to “one embodiment,” “an embodiment,” or “an example embodiment,” means that a particular feature, structure or characteristic described in connection with the embodiment is included in at least one embodiment of the present invention. Thus, appearances of the phrases “in one embodiment,” “in an embodiment,” or “an example embodiment” in various places throughout this specification are not necessarily all referring to the same embodiment, but may. Furthermore, the particular features, structures or characteristics may be combined in any suitable manner, as would be apparent to a person skilled in the art from this disclosure, in one or more embodiments. Furthermore, while some embodiments described herein include some but not other features included in other embodiments, combinations of features of different embodiments are meant to be within the scope of the invention. For example, in the appended claims, any of the claimed embodiments can be used in any combination.

All publications, published patent documents, and patent applications cited in this application are indicative of the level of skill in the art(s) to which the application pertains. All publications, published patent documents, and patent applications cited herein are hereby incorporated by reference to the same extent as though each individual publication, published patent document, or patent application was specifically and individually indicated as being incorporated by reference.

### Overview

The invention provides an improved composite material or composition for use in coverglass for satellite solar panels. Such a composition provides a flexible, conductive coverglass replacement material or composition for satellite solar panels. The invention also provides a method for manufacturing a composition as described herein. An improved coverglass replacement is also provided that may include as primary components an encapsulating resin; a conductive nano-network; and glass beads. A composition according to the present invention can be utilized in the consumer industry, as well as for both terrestrial and extraterrestrial applications. The private space industry has begun to expand greatly with regard to availability, and it has been proven to be a more economical alternative to NASA or the ESA. However, the private space industry uses more archaic solar arrays that are stiff and restricted to stiff coverglass materials. The composite according to the present invention, if used to replace these stiff materials, would minimize repairs, extend the life span of the array, and use less volume when compartmentalizing the solar array within the vehicle. The high conductivity properties of a composition as described herein also provide an advantage as a sensor to detect damage from space debris, such as meteorite penetration or ablation. It is further contemplated that a composite of the present invention may be useful as a sensor or detector in the automobile industry as a replacement touchscreen material for display screens or HUDs on electric or other modern vehicles, or even as a damage detector for windshields.

### Currently Available Compositions for Covering Satellite Solar Panels

Prior technology began with using stiff materials such as space-grade glass and acrylic. The industry then moved to use other polymers such as encapsulating silicone for flexibility in order to accommodate the flexible solar cells. This adaption for flexible solar cells was to allow the solar panels to be compartmentalized and compacted into the launch vehicle without consuming significant amount of volume within the launch vehicle, thereby reducing overall weight. However, the polymers used for these materials possess natural insulating properties that prevent them from dissipating charge buildup. The Air Force Research Laboratory (AFRL) has attempted using film depositions of semiconducting materials such as Aluminum-Tin Oxide (AZO) and Indium-Tin Oxide (ITO), however, these methods did not conduct the charge buildup very effectively and severely hindered the transparency of the materials.

On the consumer level, Tawainese and Korean technology companies (i.e., Polytron Technologies, Inc.) are trying to create a new transparent mobile phone, however the costs are high due to the complex circuitry and processing in order to make a conductive polymer. However, the present invention outperforms the Indium doped Tin Oxide or ITO composites and reduces the cost by factor by 8×. The price for an ITO coated polymer starts at $10 (100×200×0.175 mm or 4″×7.8″×6 mils) for 6.7 grams. A composition of the present invention provides a product half the weight as commercially available compositions with the same dimensions, and will cost under $3 to make, depending on the particular application.

### Compositions for Covering Satellite Solar Panels

In some embodiments, the invention provides compositions for covering satellite solar panels, comprising an encapsulating resin, a conductive nano-network, and glass beads. In some embodiments, an encapsulating resin useful for such a composition may include a polymer that does not produce outgassing, or exhibits reduced outgassing, in order to reduce condensation onto, for example, solar panels, optical elements, thermal radiators, or the like. Low outgassing polymers may provide more benefit for aerospace and/or aeronautical applications, but may not be required for terrestrial applications. Thus, in some embodiments, a low outgassing polymer may be used in a composition of the invention. In other embodiments, an encapsulating resin used in a composition as described herein may include a silicone polymer. In some specific embodiments, a composition of the invention may include a low outgassing polymer and a silicon polymer.

As used herein, a “nanocrystal” refers to a particle having a dimension smaller than 100 nanometers and composed of atoms in a crystalline arrangement. In accordance with the invention, nanocrystals may be used to manufacture or provide a covering composition such as a coverglass for a solar cell or solar panel. A composition of the present invention may be composed of nanocrystals, such as including, but not limited to, zinc oxide agglomerates, zinc oxide tetrapods, silicon, cadmium telluride (CdTe), magnetic nanoparticles, CIGS, or any other materials appropriate for the particular application. Nanocrystals may be composed of or may comprise in part, zinc acetate dihydrate, zinc chloride, zinc monohydrate, and zinc nitrate hexahydrate, zinc carbonate powder, pure zinc powder, and/or graphite powder. Metal salts may also be used to produce nanocrystals, including but not limited to, zinc salts, chalcogenide (S^{S-}, Se^{S-}, Te^{S-}), pnicnides (P³⁻, As³⁻, Sb³⁻), and any derivatives thereof. In some embodiments, the conductive nano-network component of a composition as described herein may comprise two different nanocrystals, such as including, but not limited, to zinc oxide agglomerates (ZnO-A) and zinc oxide tetrapods (ZnO-T). In some embodiments, a composition may comprise more than one nanocrystal, such as both zinc oxide agglomerates (ZnO-A) and zinc oxide tetrapods (ZnO-T). Synthesis of nanocrystals may be done using any method known in the art, such as the chemical vapor transport method, the vapor transport method, or the sol-gel process. As would be understood by one of skill in the art, modifications of any available or known methods may be made in accordance with the invention without deviating from the scope of the invention. Exemplary, non-limiting methods for preparing zinc oxide agglomerates and zinc oxide tetrapods in accordance with the invention are discussed in detail in the Examples.

As described herein, a composition for covering satellite solar panels may comprise for example, one or more of, zinc oxide agglomerates and zinc oxide tetrapods. In some embodiments, the zinc oxide agglomerates may comprise a mixture of one or more of zinc acetate dihydrate, zinc chloride, zinc monohydrate, and zinc nitrate hexahydrate. In further embodiments, the composition may also comprise citric acid and deionized water. In some embodiments, a composition as described herein may be prepared or synthesized at a molar ratio of 1:5 of the mixture to water. As described herein, molar ratios presented herein and in the Examples are exemplary in nature and, while they demonstrate desirable properties of the claimed compositions, the present invention is not intended to be limited to such ratios. One of skill in the art will understand that alternative ratios or components may produce similar results, and those compositions are intended to be encompassed within the scope of the invention.

As described herein and in the Examples, zinc oxide tetrapods may be synthesized by the chemical vapor transport method or the vapor transport method. In some particular embodiments, the chemical vapor transport method may comprise a 5:1 weight ratio of zinc carbonate powder to graphite powder. As described herein, ratios of 6:1, 5:1, 4:1, 3:1, 2:1, 1:1, or fractions thereof may also be used as appropriate with a composition as described herein, as may any other ratios appropriate for the compositions described herein.

In some embodiments, the particle size range of graphite powder may about 20 micrometers. For example, graphite powder may have a size of 5, 6, 7, 8, 9, 10, 11, 12, 13, 14, 15, 16, 17, 18, 19, 20, 21, 2, 23, 24, 25, 26, 27, 28, 29, 30, 35, 40, 45, 50 microns, or the like. In other embodiments, graphite powder may have a size range of about 1 to about 50 microns, or about 1 to about 40 microns, or about 1 to about 30 microns, or about 1 to about 20 microns, or about 3 to about 60 microns, or about 3 to about 50 microns, or about 3 to about 40 microns, or about 3 to about 30 microns, or about 2 to about 60 microns, or about 2 to about 50 microns, or about 2 to about 40 microns, or about 2 to about 30 microns.

In some embodiments, the vapor transport method comprises pure zinc powder. In some embodiments, the particle size of the zinc powder may be between about 5 to about 300 micrometers. For example, as described herein, 5, 6, 7, 8, 9, 10, 11, 12, 13, 14, 15, 16, 17, 18, 19, 20, 21, 2, 23, 24, 25, 26, 27, 28, 29, 30, 35, 40, 45, 50, 55, 60, 65, 70, 75, 80, 85, 90, 95, 100, 125, 150, 175, 200, 225, 250, 275, 300, 325, 350 microns, or the like. In other embodiments, zinc powder may have a size range of about 1 to about 300 microns, or about 1 to about 250 microns, or about 1 to about 200 microns, or about 1 to about 150 microns, or about 3 to about 300 microns, or about 3 to about 250 microns, or about 3 to about 200 microns, or about 3 to about 150 microns, or about 2 to about 300 microns, or about 2 to about 250 microns, or about 2 to about 200 microns, or about 2 to about 1500 microns.

In some embodiments, the components of a composition as described herein, including, but not limited to, an encapsulating resin, a conductive nano-network, and fused glass beads are mixed at specific ratios for maximizing the desired properties. Any desired ratio of the materials of the composition may be used, depending upon the particular application. In the present case, the ratios used were used to capture particular characteristics of a composition product, however, as would be understood, alterations in ratios may be made without altering the properties of the composition and are intended to be encompassed by the present claims. Such compositions as described herein are flexible and conductive, as would be beneficial for use in coverglass for a solar panel or array. In addition, compared to other compositions for use in solar panels, compositions of the present invention provide high conductivity, which provides advantages as a sensor to detect damage from space debris, such as meteorite penetration or ablation. Thus, in some embodiments, the invention also provides solar panels for protecting solar panels or arrays from damage from meteorites or the like.

In further embodiments, a composition of the invention may be tape-casted to form the final composition. In accordance with the invention, tape casting, also referred to as “doctor blading,” is used to create thin tapes and sheets from a slurry. Thus, in one embodiment, tape casting may be used to prepare a sheet or tape of a composition of the present invention suitable for covering the surface of a satellite solar panel. As described herein, such a process may also be used in accordance with other embodiments, to prepare other protective coverings or surfaces, such as automobile display panels or the like. Tape casting finds use in accordance with the present invention to prepare thin layers of the composition as described herein into a flat surface for subsequent drying.

As described herein, compositions of the present invention provide flexible and conductive coverings for, for example, satellite solar panels or automobile applications. In other embodiments, the conductivity of the present compositions provides an advantage for use as a sensor to detect damage from, for example, space debris such as meteorite penetration or ablation. In other embodiments, the compositions as described herein may be utilized in terrestrial, extraterrestrial, and automotive applications. In some embodiments, the automotive applications comprise a sensor or detector for replacement of touchscreen material for a display screen, or a damage detector for windshields.

As provided in the Examples, as described in detail below, zinc oxide tetrapods and agglomerates may be incorporated into a slurry batch of silicon resin and fused silica beads in any weight ratio. Tape casting of the resulting composition may then be done to apply the composition onto the solar cell or other substrate. Silica beads may also be incorporated by placing the beads with a sol-gel solution or with zinc powder to form the agglomerates and tetrapods. In some embodiments, the function of a composition as described herein is to be a coverglass or a replacement coverglass for space satellite solar panels that permit flexible solar cells to be rolled or folded without fracturing. In other embodiments, a composition as described herein may permit conductivity and maximize transparency to extend the lifespan of a solar panel and thus also extend the lifespan of a satellite. A composition may be adhered to the surface of a solar cell, or it may be tape casted unto the substrate and allowed to cure and solidify.

In some embodiments, compositions as described herein may be utilized in terrestrial, extraterrestrial, and/or automotive applications. As described herein, components of the presently described composition may be altered depending on the particular application to optimize the most beneficial properties. For example, aerospace and/or aeronautical applications may benefit from inclusion of a low outgassing polymer in a composition of the invention as described above, or terrestrial applications may instead benefit from a silicon polymer. Polymers are well known in the art, and one of skill in the art would be capable of selecting an appropriate polymer for the particular application as appropriate.

In accordance with the invention, a composition as described herein provides an advantage over other materials and compositions currently available in the art. For example, a composition of the invention may provide an extended life span compared to other materials or compositions when used as a cover material for a solar panel (i.e., coverglass or other protective material) or other particular application or item to which or onto which the composition is applied. In another embodiment, an automotive application may include, but is not limited to, a sensor or detector for replacement of touchscreen material for a display screen or HUD. In other embodiments, compositions of the present invention may be useful for a damage detector for windshields. Accordingly, these and other related applications are intended to be encompassed by the present invention.

Compositions according to the present invention that are prepared or manufactured from zinc oxide nanocrystals and nanoparticles may exhibit particular characteristics: (1) optimal transparency, thus providing a more favorable coverglass; 2) mechanical flexibility, which is beneficial for transportation and longevity; and 3) optimal conductivity. In addition, the weight fraction of the semi-conducting material can be increased within the composite without severely limiting transparency of the resulting composition. The advantages of this composite permit higher conductivity, as well as being capable to increase the weight fraction of the semi-conducting material within the composite without severely limiting transparency.

In some embodiments, the incorporation of ZnO-T and ZnO-A in a composition of the invention in particular weight ratios provides alternative materials that may be used in an overall composition. In other embodiments, glass beads may be used in set weight ratios and tape casted unto the solar cell or substrate. In other embodiments, magnetically aligned zinc oxide nanorods may be used in a composition of the invention in order to provide a controlled directional circuit within the coverglass replacement or composition.

As described herein, the present compositions may be used in the consumer industry, as well as terrestrial and extraterrestrial applications. The private space industry has expanded in terms of availability and expansion, and it has been proven to be a more economical alternative to NASA or the ESA. However, the private sector uses archaic solar arrays that are stiff and are restricted to stiff coverglass materials. Compositions of the present invention would provide a way to minimize repairs for autonomous vehicles and extend the life span of solar arrays. In addition, less space and volume may be required when compartmentalizing a solar array within a transport vehicle. In addition to the high conductivity of compositions as described herein, they may also double as sensor means for detection of damage from space debris meteorite penetration or ablation.

In some embodiments, a composition as described herein further comprises glass beads for reduction of internal light scattering. In accordance with the invention, glass beads may comprise silica/quartz, or an engineering ceramic. Glass beads may be made from any appropriate materials that provides the properties needed or desired for a composition of the invention. Beads useful for a composition of the invention may be fused beads, and may promote the transmission of light and block or absorbs cosmic and gamma radiation. Glass beads may be any size appropriate for a composition as described herein, for example a coverglass for a solar panel. Glass beads may be obtained commercially, or may be manufactured in any size or using any appropriate materials. For example, in some embodiments, glass beads as described herein may comprise a size from about 5 microns to about 50 microns, including 5, 6, 7, 8, 9, 10, 15, 20, 25, 30, 35, 40, 45, or 50 microns. In other embodiments, glass beads may have a size range of about 1 to about 50 microns, or about 1 to about 40 microns, or about 1 to about 30 microns, or about 1 to about 20 microns, or about 3 to about 60 microns, or about 3 to about 50 microns, or about 3 to about 40 microns, or about 3 to about 30 microns, or about 2 to about 60 microns, or about 2 to about 50 microns, or about 2 to about 40 microns, or about 2 to about 30 microns. In other embodiments, glass beads may be mixed at a weight ratio of 0.9:1 of beads to resin, or a weight ratio of 2:1 of beads to resin. For example, ratios of 0.5:1, 0.6:1, 0.7:1, 0.8:1, 0.9:1, 1:1, 1.1:1, 1.2:1, 1.3:1, 1.4:1, 1.5:1, 1.6:1, 1.7:1, 1.8:1, 1.9:1, 2:1, 2.1:1, 2.2:1, or the like. Any particular ratio may be used in accordance with the invention, and may be optimized according to the particular application. In addition to glass beads, a composition of the invention may further comprise a shear thinning agent.

### Coverglass for Satellite Solar Panels

In some embodiments, a composition as described herein may be used to produce or manufacture a coverglass or other protective material. Particular applications for which such compositions are useful are in the production of coverglass for satellite solar panels. Such embodiments are described herein and in the Examples. Manufacture of coverglass for satellites to be transported to space are encompassed within the scope of the present invention, as well as coverglass replacement for currently available composites used on satellite solar panels. Coverglass or replacement coverglass provide protection of solar panels from environmental conditions such as radiation or oxygen bombardment, as well as debris, such as debris found in space, including meteorite damage.

In some embodiments, a coverglass made from a composition as described herein is flexible and conductive, providing an advantage over coverglass currently available in the art. A particularly useful application of compositions and/or coverglass as described herein is in transport of the solar panels or coverglass. The flexibility of the compositions of the invention results in a reduced volume required for compartmentalizing the solar array within a transport or other vehicle.

In some embodiments, a coverglass or solar array prepared or manufactured with a composition as described herein may exhibit an extended shelf life compared to a coverglass or solar array made from other materials, and wherein the volume required for compartmentalizing the solar array within the vehicle is reduced. Coverglass or solar panels as described herein that are prepared or manufactured using a composition as described herein may be flexible and conductive, providing increased protection to a satellite solar panel or other surface.

Methods for Producing Compositions and/or Coverglass for Covering Satellite Solar Panels

In some embodiments, the invention provides a method for producing a composition as described herein, comprising: mixing an encapsulating resin, a conductive nano-network, and fused glass beads at a specific ratio, wherein the ratio maximizes the inherent properties; and tape casting the mixture to create the composition. In some embodiments, a method as described herein involves mixing the composition components in a specific ratio for the particular application, such that the properties of the components are optimized.

In embodiments of the invention, the method may be used to produce a composition as described herein, both above, and in the Examples. The methods may provide a composition substantially or entirely as described herein. For example, as described in detail above, the encapsulating resin may optionally include any components described herein for a composition of the present invention, including a low-out gassing polymer, or an encapsulating silicone polymer, or both. One of skill in the art will understand that a method for producing a composition as described herein may differ somewhat from the methods described herein without deviating from the scope of the present invention.

Methods for producing a composition as described herein may encompass any methods known in the art, and may be modified as necessary for the particular application. For example, the vapor-transport method may involve pure zinc powder as described herein, or may involve the use of other metal oxides as described herein for producing a composition of the invention. Temperatures and concentrations described herein may also be modified as necessary for the particular application without altering the final composition.

The sol-gel process may be used in methods as described herein, with a mixture of zinc acetate, citric acid, and water as described in the Examples.

In other embodiments, zinc oxide tetrapods and agglomerates may be incorporated into a slurry batch of silicon resin and fused silica beads in set weight ratios and tape-casted onto the solar cell or substrate. Glass beads may be incorporated by combining them with a sol-gel solution or with zinc powder to form the agglomerates and tetrapods, respectively. The composition may be adhered to a surface, for example of a solar cell, or tape-casted onto a substrate and allowed to cure and solidify.

As described herein, a composition of the present invention may be used in the consumer industry, as well for both extra and terrestrial purposes. Additional applications include a sensor/detector in the automobile industry in terms of replacement touchscreen material for the display HUD on electric or other modem vehicles; or even as a damage detector for windshields. The benefits are high, and the costs are low, indicating the usefulness of compositions as described. This novel composite may be referred to as V.S. or Vitreum Scutum.

### EXAMPLES

### Example 1—Synthesis of Zinc-Oxide Tetrapods or Agglomerates

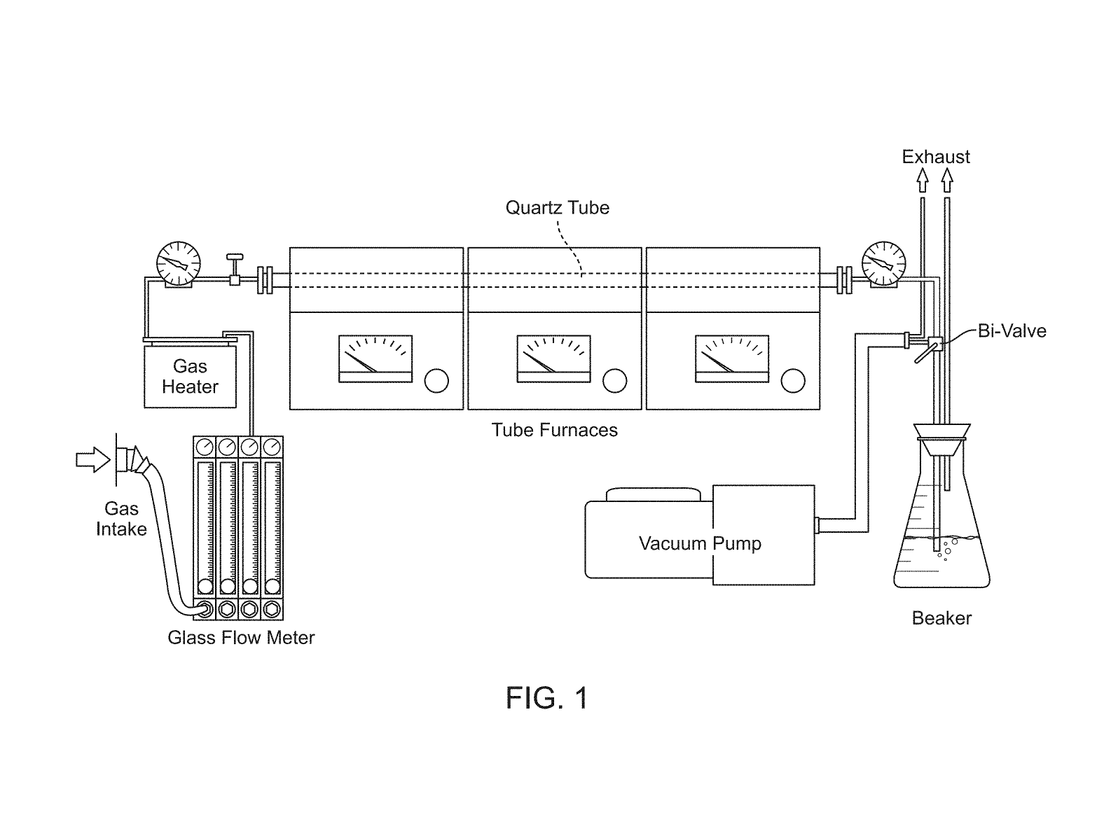

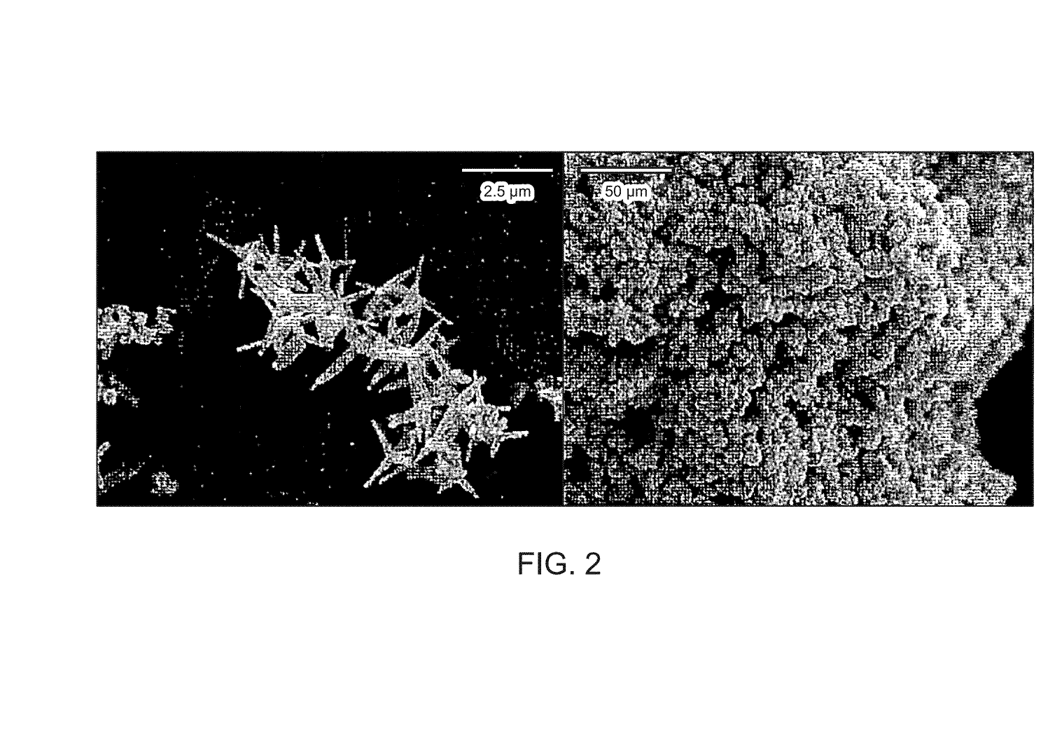

An experimental set-up for synthesizing zinc oxide tetrapods or agglomerates is shown as FIG. 1. A batch of either zinc oxide tetrapods (ZnO-T) or agglomerates (ZnO-A) was synthesized by the vapor transport method and sol-gel process, respectively (FIG. 2).

For the process of the vapor-transport method, a boat with pure zinc powder was placed in a horizontal tube furnace with the atmosphere purged and replaced with a mixture of oxygen and argon. The zinc vapor flowed down the quartz tube and condensed on a cooler surface such as silicon wafer and nucleates into tetrapods (FIG. 2).

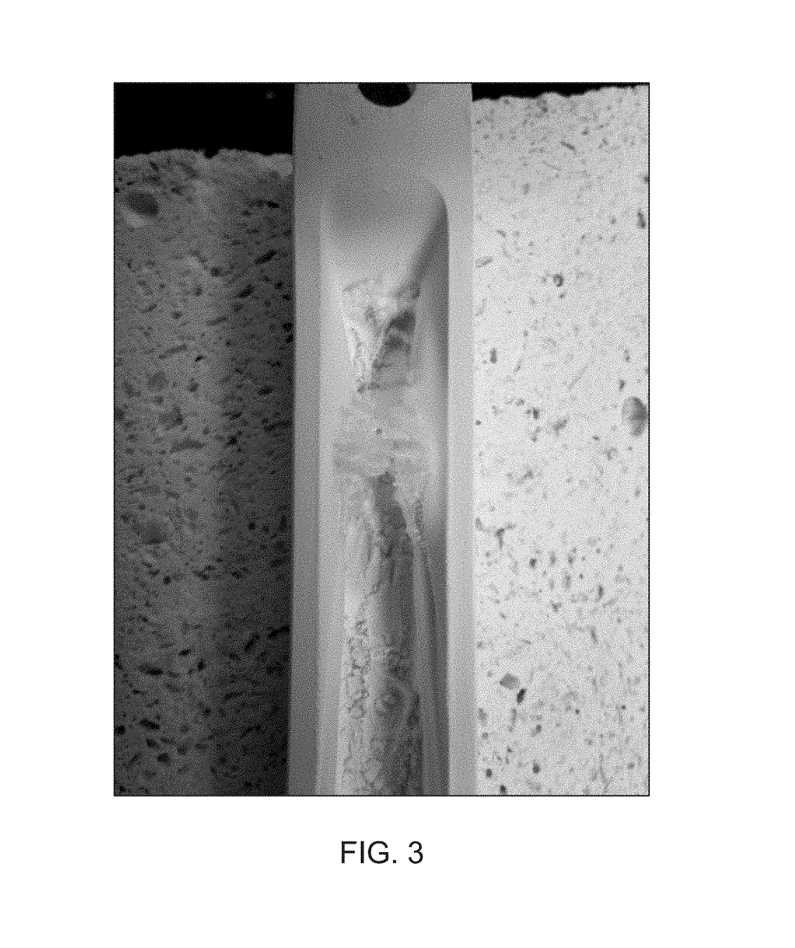

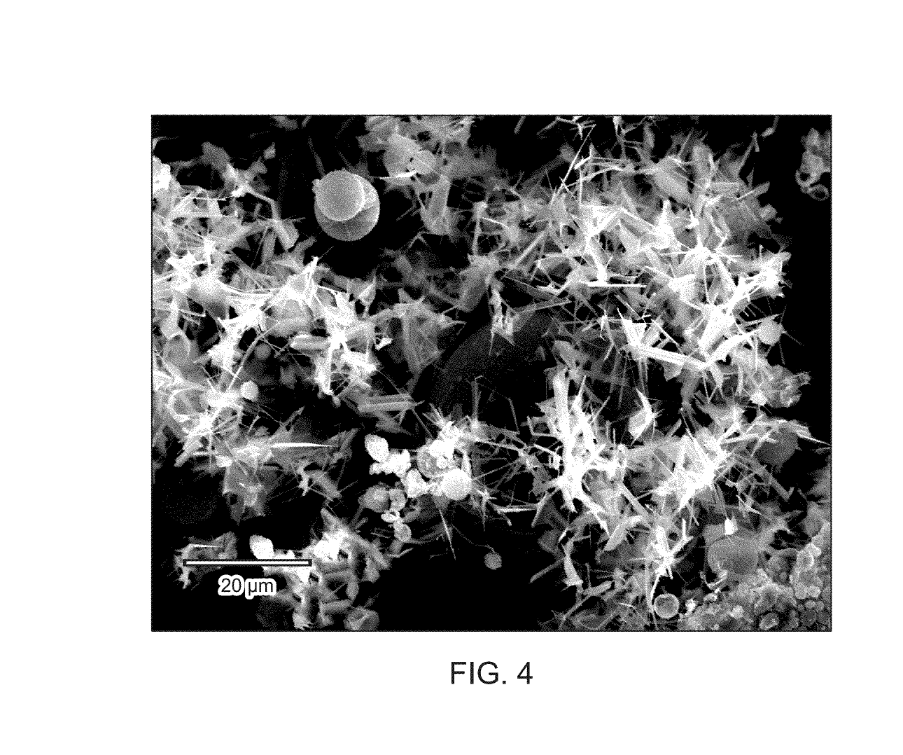

For the sol-gel process, a mixture of zinc acetate, citric acid, and water were placed into a boat, which was then placed into a tube furnace in a pure oxygen atmosphere. The heat from the furnace forced the mixture to combust and incinerate into zinc oxide agglomerates (FIG. 2). A prospective view of a solar cell utilizing a composition of the present invention is provided in FIGS. 3 and 4.

The zinc oxide tetrapods and agglomerates were then incorporated into a slurry batch of silicon resin and fused silica beads in set weight ratios and tape casted onto the solar cell or substrate. The beads can also be incorporated by placing the beads with the sol-gel solution or with the zinc powder to form the agglomerates and tetrapods, respectively. The composite can be adhered to the surface of the solar cells or tape-casted unto the substrate and allowed to cure and solidify.

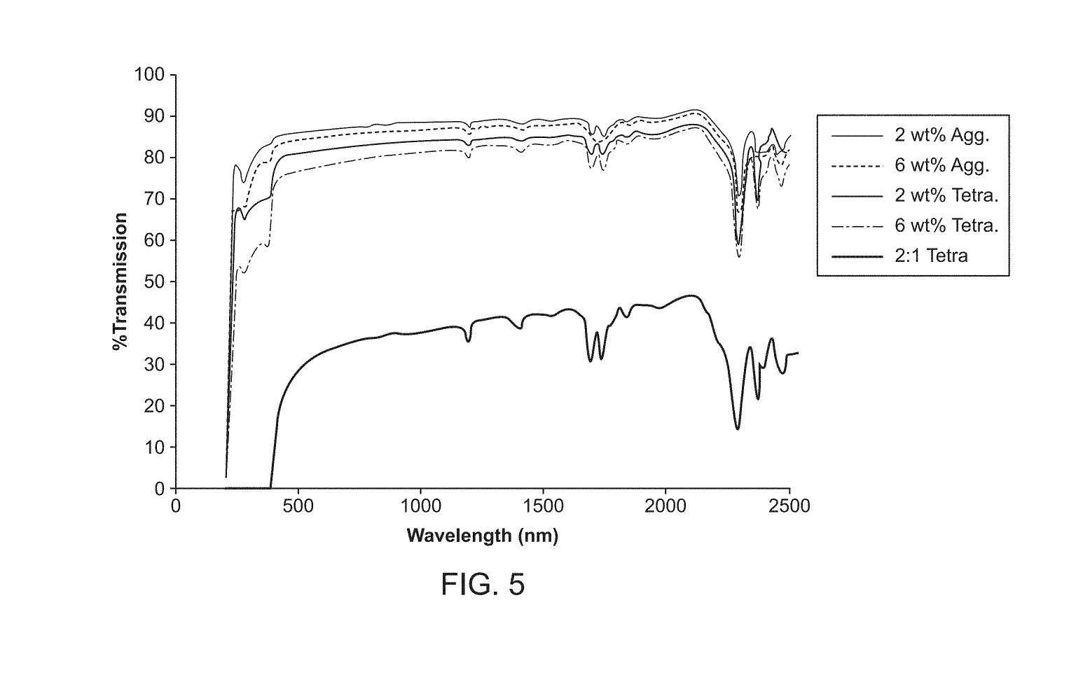

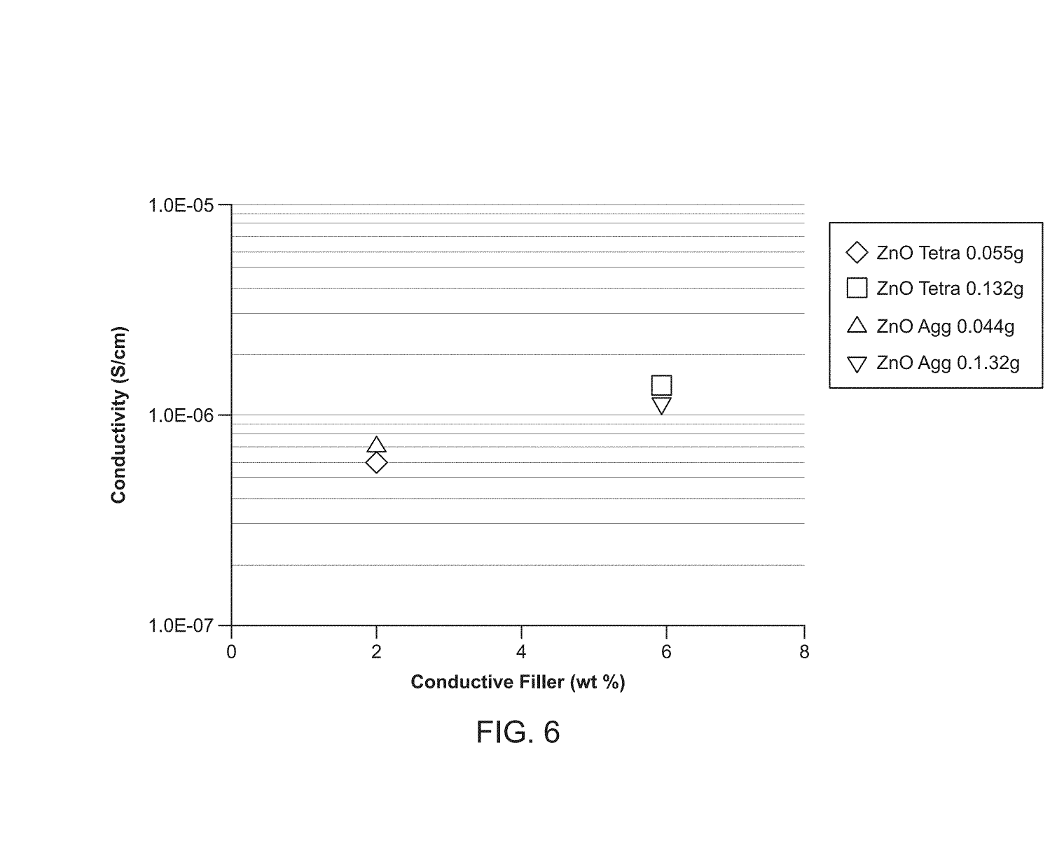

The incorporation of the ZnO-T and ZnO-A in the composite in set weight ratios provide alternative materials to be used in the overall composite. Another alternative is to use fused silica beads in set weight ratios and tape casted unto the solar cell or substrate. Alternatively, magnetically aligned zinc oxide nanorods in the composite to provide a controlled directional circuit within the cover glass replacement or composite. FIGS. 5 and 6 demonstrate the increased weight fraction of the semi-conducting material within the composition of the invention without severely limiting transparency.

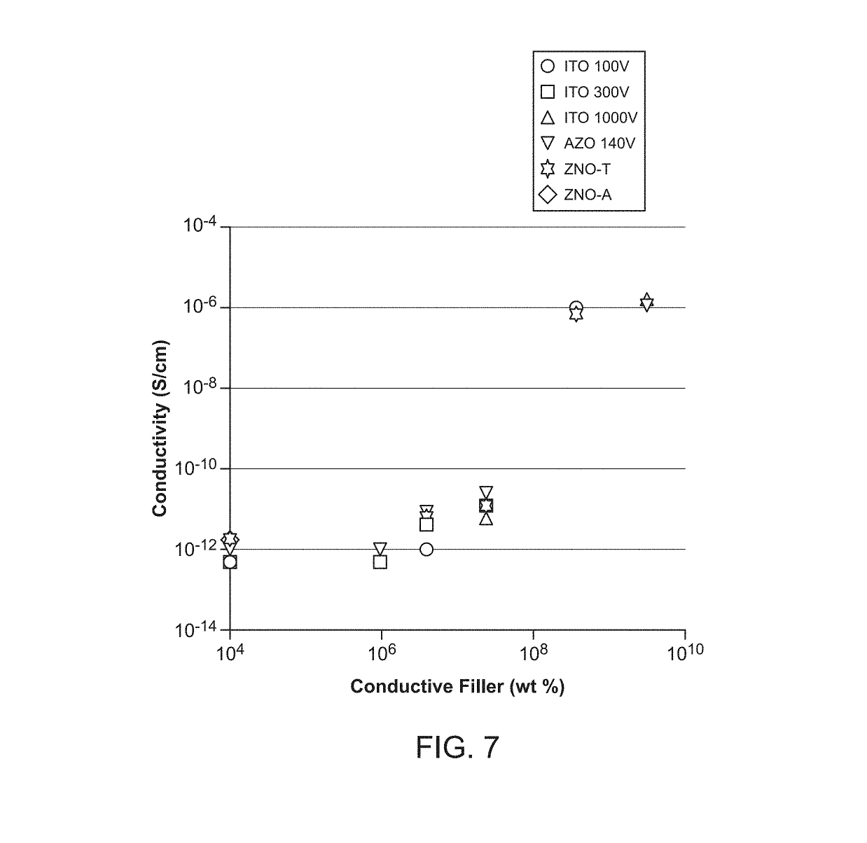

One advantage of the present composition is the higher conductivity, as shown in FIG. 7. Further, the weight fraction of the semi-conducting material can be increased within the composite without severely limiting transparency.

A composite according to the present invention includes zinc oxide nanocrystals and nanoparticles having one or more of the following primary criteria: (1) optimal transparency; (2) mechanical flexibility; and (3) optimal conductivity.

The incorporation of the ZnO-T and ZnO-A in the composite in set weight ratios provides alternative materials to be used in an overall composite. Another alternative is to use magnetically aligned zinc oxide nanorides to provide a controlled directional circuit within the cover glass replacement or composite.

The composition had three major components: 1) the encapsulating resin (depending on its application the resin composition will vary), 2) the conductive nano-network, and 3) the fused silica (quartz) beads. For aerospace and aeronautical applications, the use of a low out gassing polymer for the encapsulating resin is required; whereas, that requisite isn't necessary for terrestrial applications. There are two different nanocrystals that are used for the network, the first is the zinc oxide agglomerates and the zinc oxide tetrapods. The three components are mixed at specific ratios for maximizing the inherit properties and tape casted to create the final product.

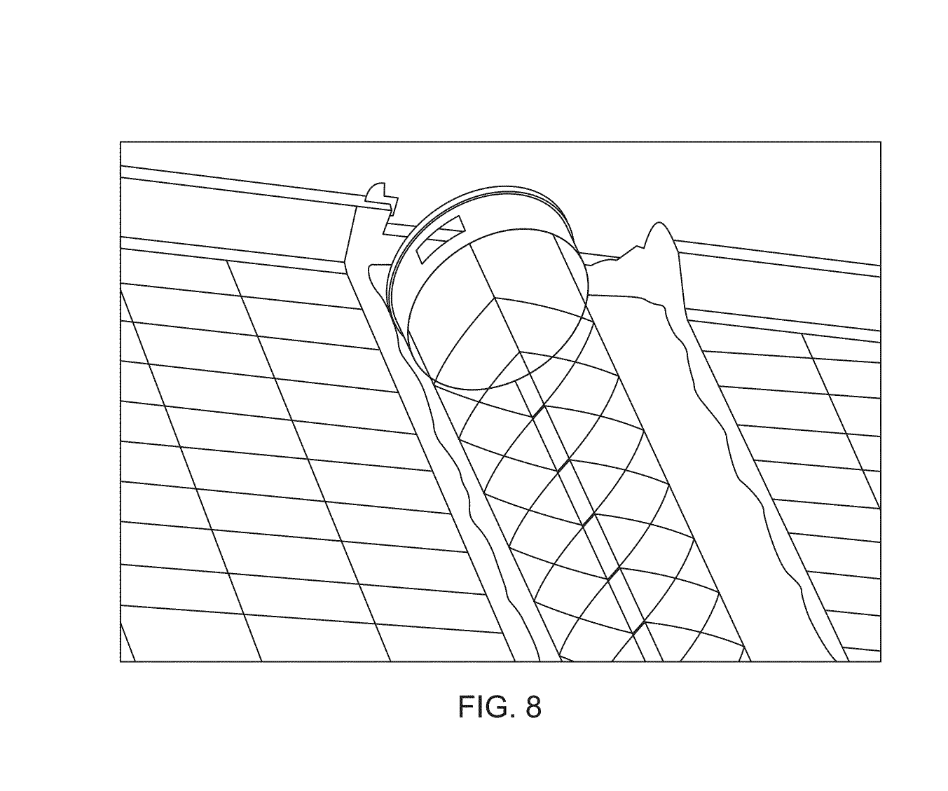

The novel composite can be used in the consumer industry as well for both extra and terrestrial purposes. The private space industry is beginning to explode in terms availability and expansion, and it has been proven to be a more economical alternative to NASA or the ESA. However, they also use the archaic solar arrays that are stiff and are restricted to stiff coverglass materials. If they switch to flexible solar arrays they may be in need to use the novel composite to minimize repairs for their autonomous vehicles and extend the life span of the array; and use less volume when compartmentalizing the solar array within the vehicle. In addition to the novel composite's inherit properties for high conductivity it can also double as a sensor to detect damage from space debris such meteorite penetration or ablation. FIG. 8 shows a solar array on the International Space Station (ISS) that was penetrated by a meteorite and was only discovered when an astronaut took a picture and noticed light corning through a hole.

### Example 2—Synthesis of Zinc Oxide Agglomerates

The synthesis of the zinc oxide tetrapods (ZnO-T) and zinc oxide agglomerates (ZnO-A) were carried out in a makeshift tube furnace made from three different tube furnaces with an intake gas flow meter, preheater, vacuum pump, and a beaker to collect any airborne particulates (FIG. 1).

The zinc oxide agglomerates can be made by mixing zinc salts in the appropriate stoichiometric amounts with citric acid and deionized water (1:5 molar ratio of mixture to water, respectfully). The zinc salts that were and can be used are: zinc acetate dihydrate, zinc chloride, zinc monohydrate, zinc nitrate hexahydrate. When mixed, the compound is stirred on a hot plate until everything is dissolved and heated at around 80° C. for approximately five minutes. Then the compound will begin to gel upon cooling when this occurs it is poured into a crucible, which is then placed into a tube furnace with temperature and atmospheric controls with a quartz tube. The atmosphere in the quartz tube is purged and replaced with a pure oxygen atmosphere with a continuous flow rate (throughout the process) at approximately 100 sccm. The temperature is set for 900° C. at which it is held for approximately fifteen minutes. After allowed to cool down, the finished product is removed and collected from the crucible.

### Example 3—Synthesis of Zinc Oxide Tetrapods

The two primary methods for synthesizing ZnO tetrapods are the chemical vapor transport method and the vapor transport method. For the chemical vapor transport method, the process begins with a 5:1 weight ratio of zinc carbonate powder (ZnCO₃*2Zn(OH)₂*H₂O) to graphite powder (particle size range approximately 20 micrometers). The sample is placed in a crucible within a quartz tube which is then placed in a tube furnace with a silicon wafer <111> positioned either transversal downstream or parallel above the crucible, with respect to the tube furnace. The tube furnace is set to 900° C. with the atmosphere purged and replaced with 0.5-5% oxygen mixed with an inert gas such as nitrogen or argon, with a flow rate of approximately 500 sccm. The temperature is held at 900° C. for about ten minutes, and after sufficient cooling it removed and the ZnO tetrapods are collected from the wafer.

The vapor transport method. This method uses pure zinc powder (5-300 micrometers for particle size) is placed into a crucible and into a quartz tube for the tube furnace. The tube furnace is set between 700-850° C. with an ambient atmosphere of 0.5-5% oxygen in an inert carrier gas (both variables depend on the nanocrystals the operator is trying to achieve). The flow rate is set between 100-300 sccm depending on the distance between the crucible and the silicon wafer. Then the temperature is held for approximately thirty or more minutes depending on amount to be synthesized, ad then the sample is cooled and collected.

### Example 4—Mixing with Space Grade Encapsulating Resin

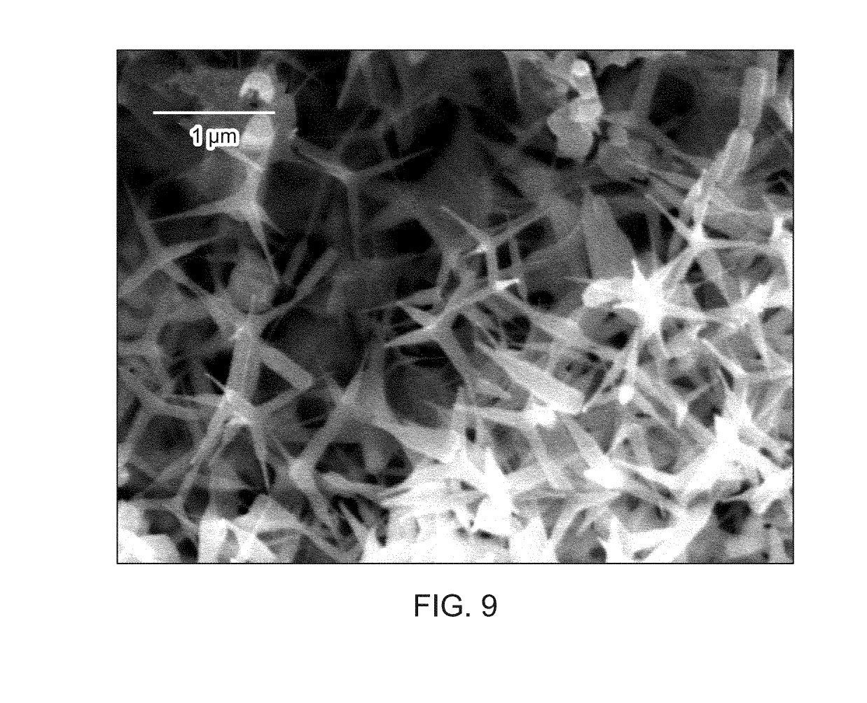

The resin is typically a low out-gassing polymer suitable for low or non atmosphere environments. The resin that is typically used is an encapsulating silicone polymer from Dow-Corning or NuSil labeled as: DC3-500. In order to reduce internal light scattering the two-part polymer compound is mixed with glass beads typically fused silica (quartz) or any other engineering ceramic that promotes the transmission of light and blocks or absorbs cosmic and gamma radiation. The typical bead sizes range from 5 micron to 50 microns to minimize voids, and they are mixed at a weight ratio of 0.9:1 for beads to resin. For larger amounts of beads to be incorporated into the composite a shear thinning agent is required, but it is possible. It has been tested and proved that 2:1 weight ratio (beads:resin) gives the best optical transparency. Then the appropriate amounts of ZnO agglomerates or tetrapods can be added depending on the desired conductivity or optical transmissivity. It was discovered that a range of 1-6 wt % of ZnO nanocrystals was desirable, but more research is in the works to pinpoint optimal amount. An SEM image of ZnO-T is shown in FIG. 9.

### Example 5—Tape Casting and Curing

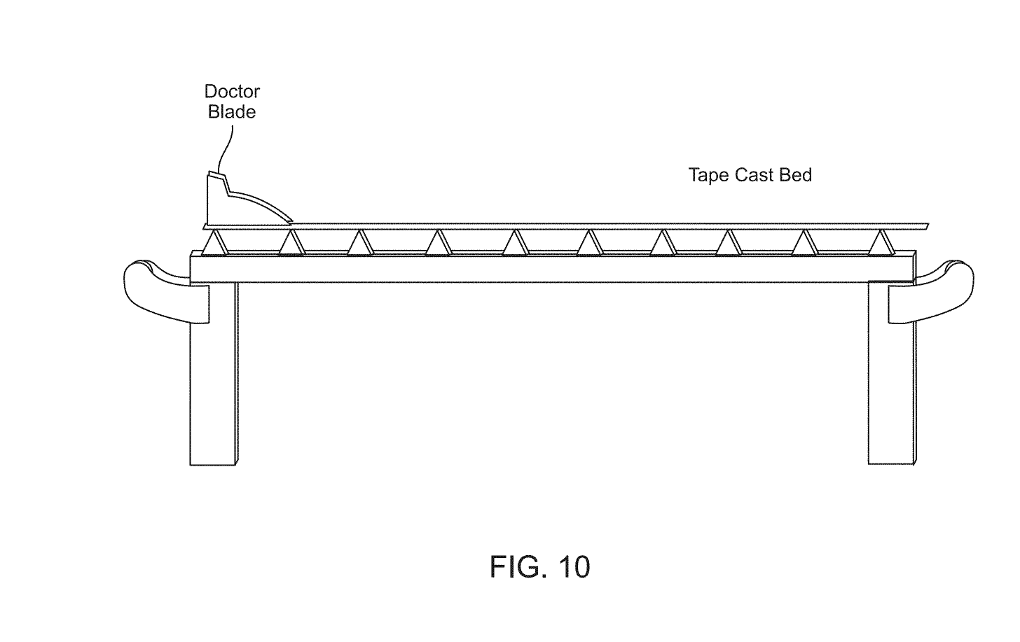

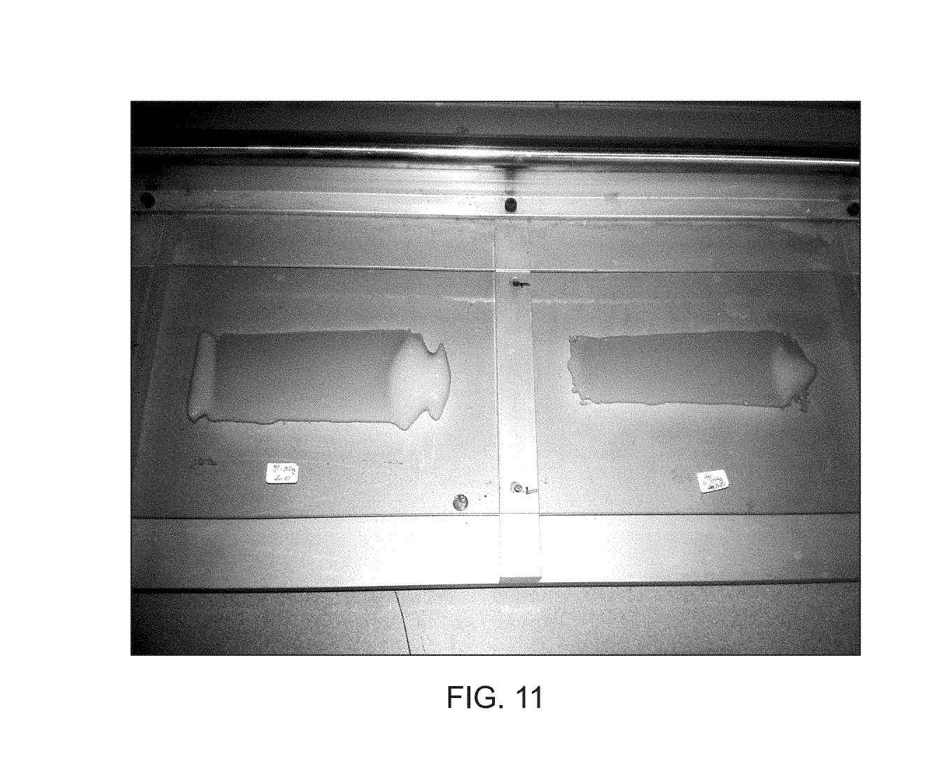

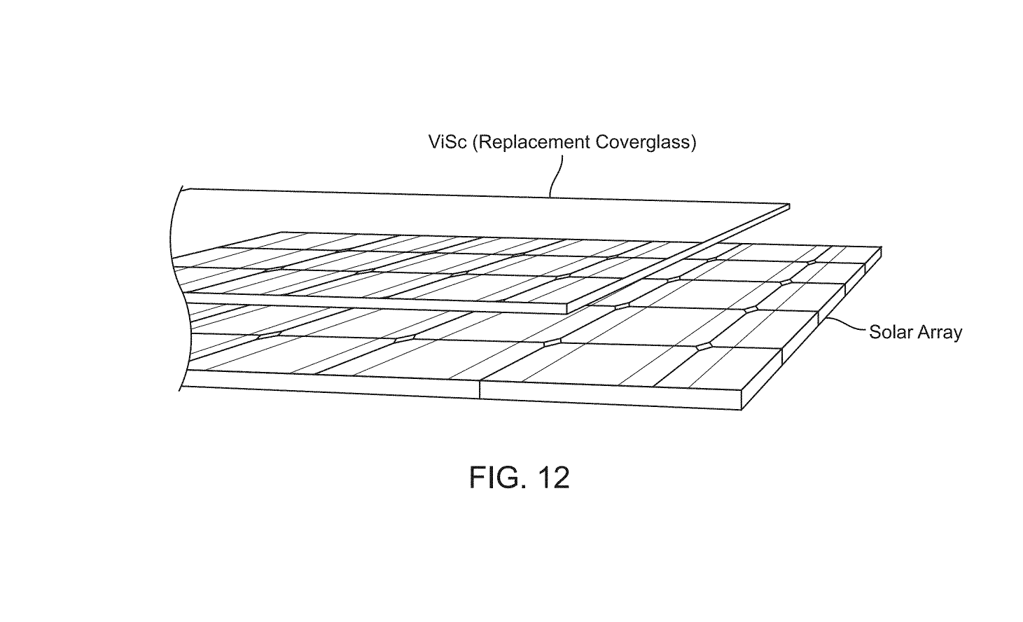

Once everything is mixed, the composition was tape-casted unto a substrate (i.e., glass) using a doctor blade system (FIG. 10); and cured for approximately twelve hours depending on (the type of encapsulating polymer) whether it would be silicone or any other type of engineering polymer with the following properties: optical transparency, low out-gassing properties, oxygen bombardment resistant, and relatively high electrical conductivity. The tape casted composite was either laid unto a substrate or collected on a roll for storage or shipping. An image of a casted composite is shown in FIG. 11. A side view of a final application of a coverglass in accordance with the invention to a solar array is shown in FIG. 12.

What is claimed is:

1. A composition for covering satellite solar panels, comprising: an encapsulating resin, a conductive nano-network, and glass beads.

2. The composition of claim 1, wherein the encapsulating resin optionally includes a low-out gassing polymer, or an encapsulating silicone polymer, or both.

3. The composition of claim 2, further comprising glass beads for reduction of internal light scattering.

4. The composition of claim 3, wherein the glass beads comprise silica/quartz or an engineered ceramic.

5. The composition of claim 1, wherein the glass beads are configured to promote the transmission of light and block or absorb cosmic and gamma radiation.

6. The composition of claim 1, wherein the glass beads comprise a size from about 5 microns to about 50 microns

7. The composition of claim 1, wherein the glass beads are mixed at a weight ratio of 0.9:1 of beads to resin or a weight ratio of 2:1 of beads to resin.

8. The composition of claim 1, further comprising a shear thinning agent.

9. The composition of claim 1, wherein the conductive nano-network comprises two different nanocrystals.

10. The composition of claim 9, comprising a range of 1-6 wt % of ZnO nanocrystals.

11. The composition of claim 9, wherein the two different nanocrystals comprise zinc oxide agglomerates and zinc oxide tetrapods.

12. The composition of claim 11, wherein the zinc oxide agglomerates comprise a mixture of one or more of zinc acetate dihydrate, zinc chloride, zinc monohydrate, and zinc nitrate hexahydrate.

13. The composition of claim 12, further comprising citric acid and deionized water.

14. The composition of claim 13, wherein the composition is prepared at molar ratio of 1:5 of the mixture to water.

15. The composition of claim 11, wherein the zinc oxide tetrapods are synthesized by the chemical vapor transport method or the vapor transport method.

16. The composition of claim 15, wherein the chemical vapor transport method comprises a 5:1 weight ratio of zinc carbonate powder to graphite powder.

17. The composition of claim 16, wherein the particle size range of graphite powder is about 20 micrometers.

18. The composition of claim 15, wherein the vapor transport method comprises pure zinc powder.

19. The composition of claim 18, wherein the particle size of the zinc powder is between about 5 to about 300 micrometers.

20. The composition of claim 1, wherein the composition is flexible and conductive.

21. A method for producing the composition of claim 1, comprising:
mixing an encapsulating resin, a conductive nano-network, and fused glass beads at a specific ratio, wherein the ratio maximizes the inherent properties; and
tape casting the mixture to create the composition.

22. The method of claim 21, wherein the encapsulating resin optionally includes a low-out gassing polymer, or an encapsulating silicone polymer, or both.

23. The method of claim 21, wherein the glass beads comprise silica/quartz or an engineering ceramic.

24. The method of claim 21, wherein the glass beads are configured to promote the transmission of light and block or absorb cosmic and gamma radiation.

25. The method of claim 21, wherein the glass beads comprise a size from about 5 microns to about 50 microns

26. The method of claim 21, wherein the glass beads are mixed at a weight ratio of 0.9:1 of beads to resin or a weight ratio of 2:1 of beads to resin.

27. The method of claim 21, wherein the composition further comprises a shear thinning agent.

28. The method of claim 21, wherein the conductive nano-network comprises two different nanocrystals.

29. The method of claim 28, comprising a range of 1-6 wt % of ZnO nanocrystals.

30. The method of claim 28, wherein the two different nanocrystals comprise zinc oxide agglomerates and zinc oxide tetrapods.

31. The method of claim 30, wherein the zinc oxide agglomerates comprise a mixture of one or more of zinc acetate dihydrate, zinc chloride, zinc monohydrate, and zinc nitrate hexahydrate.

32. The method of claim 31, further comprising citric acid and deionized water.

33. The method of claim 32, wherein the composition is prepared at molar ratio of 1:5 of the mixture to water.

34. The method of claim 30, wherein the zinc oxide tetrapods are synthesized by the chemical vapor transport method or the vapor transport method.

35. The method of claim 34, wherein the chemical vapor transport method comprises a 5:1 weight ratio of zinc carbonate powder to graphite powder.

36. The method of claim 35, wherein the particle size range of graphite powder is about 20 micrometers.

37. The method of claim 34, wherein the vapor transport method comprises pure zinc powder.

38. The method of claim 37, wherein the particle size of the zinc powder is between about 5 to about 300 micrometers.
